(19) United States
(12) Patent Application Publication
(10) Pub. No.: US 2011/0223332 A1
(43) Pub. Date: Sep. 15, 2011

(54) METHOD FOR DEPOSITING CUBIC BORON NITRIDE THIN FILM

(75) Inventors: Young Joon BAIK, Seoul (KR); Jong Keuk PARK, Seoul (KR); Wook Seong LEE, Seoul (KR)

(73) Assignee: KOREA INSTITUTE OF SCIENCE AND TECHNOLOGY, Seoul (KR)

(21) Appl. No.: 13/047,405

(22) Filed: Mar. 14, 2011

(30) Foreign Application Priority Data
Mar. 15, 2010 (KR) 10-2010-0022966

(51) Int. Cl. C23C 16/00; C23C 14/35

(52) U.S. Cl. 427/248.1; 204/192.16

(57) ABSTRACT

The present invention relates to a method for depositing a cBN thin film on a substrate to obtain an abrasive material by physical vapor deposition carried out under an atmosphere composed of an inert gas and hydrogen. The abrasive produced by the inventive method comprises the cBN thin film attached firmly to the substrate, which has excellent hardness and durability.

### FIELD OF THE INVENTION

The present invention relates to a method for depositing a cubic boron nitride (cBN) thin film, which can be used for the abrasion resistance coating of abrasion resistance parts of cutting and molding tools.

### BACKGROUND OF THE INVENTION

Cutting tools used in cutting processes for manufacturing shaped goods are required to have improved mechanical properties which are suitable for processing newly developed materials having refined properties. The conventional WC—Co carbide tools or high-speed steel tools are generally equipped with a thin film coating of a high hardness material such as TiAlN which has a hardness of 30 GPa. However, such a degree of hardness is still not sufficiently high for a cutting process of new materials which have been recently developed, and thus, the development of a novel thin film material having a super-hardness of 50 GPa or more is required.

cBN(cubic boron nitride) has a hardness of 60 GPa which is only slightly lower than that of diamond, and it does not react with Fe, Ni, or related alloys unlike diamond which reacts with Fe to form carbides. Thus, cBN is regarded as a next-generation coating material that can be used for general purposes which include working with iron containing metals at high temperatures (A. Richer, Cutting Tool Engineering, 60, 46 (2008)).

cBN is not formed in nature and it must be synthesized by a process conducted under high temperature, high pressure conditions. Accordingly, the deposition of a thin film form of cBN is very difficult, and an example of depositing a cBN thin film has been reported only recently (W. J. Zhang et al., J. Phy. D: Appl. Phys., 40, 6159 (2007)). Unlike other hard thin films, in the application of a cBN thin film to a cutting tool, the most important problem to solve is the fact that the adhesion strength of a cBN thin film to a base material is generally very weak (A. Richer, Cutting Tool Engineering, 60, 46 (2008)).

BN (boron nitride) exists in various crystalline forms, inclusive of the cubic and hexagonal forms. As the hexagonal form is more stable than cBN, the selective deposition of cBN may be carried out using high energy ions (W. J. Zhang et al., J. Phy. D: Appl. Phys., 40, 6159 (2007)). However, the collision of such ions induce the generation of compressive residual stress which amounts to 25 GPa in case of cBN (S. Ulrich et al., Surf. and Coatings Tech., 200, 7 (2005)), while in case of commonly used hard thin films, the magnitude of compressive residual stress is below 5 GPa. Such a high compressive residual stress generated in the cBN thin film deposition process is concentrated at the coating layer-base material in the face, leading to the detachment of the films. To solve this problem, many methods have been suggested to reduce the compressive residual stress and to enhance the adhesion strength.

For example, a method for reducing the energy level of Argon (Ar) ions used in a thin film deposition process has been studied (A. Schutze et al., Surf. and Coatings Tech., 97, 33 (1997)). However, when the ion collision energy decreases below a critical value due to the low Ar ion energy level, the hBN(hexagonal boron nitride) content in the film tends to increase by suppressing nucleation and growth of cBN.

Further, a method for reducing the collision energy by using the ions of He or Ne, ions lighter than Ar ion, has been suggested (A. Schutze et al., Surf. and Coatings Tech., 97, 33 (1997)). However, this method gave the problem of decreased cBN content due to the decreased mass of the ions.

In addition, a method for reducing the residual stress by adding oxygen has been studied (S. Ulrich et al., Surf. and Coatings Tech., 200, 7 (2005)). However, as boron can be easily oxidized to form boron oxide, the mechanical properties of the film became poor.

Accordingly, there exists a need to develop a novel method for depositing a thin cBN film at a reduced level of compressive residual stress without reducing the ion collision energy and without oxidizing the film.

### SUMMARY OF THE INVENTION

It is, therefore, an object of the present invention to provide a novel method for depositing a thin cubic boron nitride film on a substrate, the film containing no oxidic species and being firmly attached to the substrate with an improved adhesion strength with the substrate.

In accordance with the present invention, there is provided a method for depositing a cBN thin film on a substrate by carrying out physical vapor deposition under an inert gas atmosphere, wherein hydrogen is added to the inert gas in order to reduce the compressive residual stress of the deposited thin film.

### BRIEF DESCRIPTION OF THE DRAWINGS

The above and other objects and features of the present invention will become apparent from the following description of preferred embodiments given in conjunction with the accompanying drawings, which respectively show:

FIG. 1: TEM image showing the cross sections of non-specific thin film of aBN, hBN, and cBN layer deposited on a Si substrate;

FIG. 2: enlarged TEM image of the cross section of hBN layer;

FIG. 3: molecular structure model of hBN layer whose surface consists of sp² bonds;

FIG. 4: molecular structure model of hBN layer whose surface consists of sp^{a} bonds generated by absorbed hydrogen;

FIG. 5: FT-IR spectra of the thin films obtained in Example and Comparative Example;

FIG. 6: enlarged cBN peaks in the FT-IR spectra taken for the thin films obtained in Example and Comparative Example;

FIG. 7: the changes of compressive residual stress and the cBN content in cBN thin films as a function of the volume of added hydrogen;

FIG. 8: the change of the Ar content in the thin film as a function of the volume of added hydrogen; and

FIGS. 9a and 9b: SEM images showing the cross sections of the cBN thin films obtained in Example and Comparative Example, respectively.

### DETAILED DESCRIPTION OF THE PREFERRED EMBODIMENTS

The present invention should be understood based on correlations between the microstructural characteristics observed during the deposition of a cBN thin film, the penetration of the colliding inert gas atoms into the thin film, and the influence thereof on the surface bonding structure.

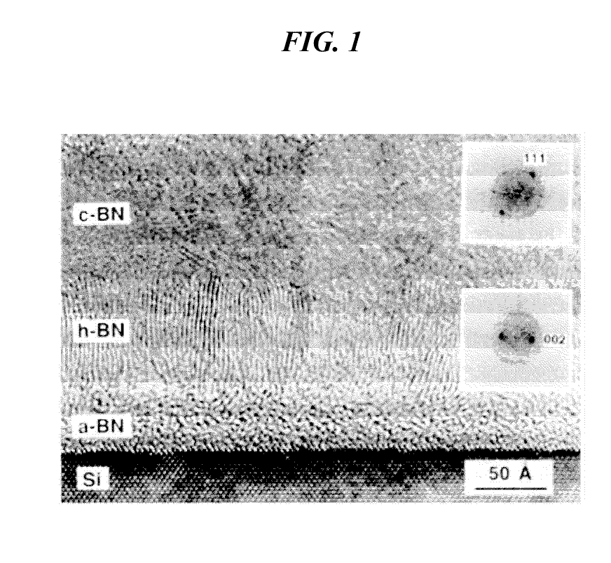

FIG. 1 is a TEM image showing the cross section of boron nitride thin film deposited on a Si substrate. In general, an aBN (amorphous boron nitride) layer, an hBN (hexagonal boron nitride) layer, and a cBN layer are sequentially deposited on the substrate. It is understood that the pre-deposition of an aBN or hBN layer is necessary for the formation of a cBN layer.

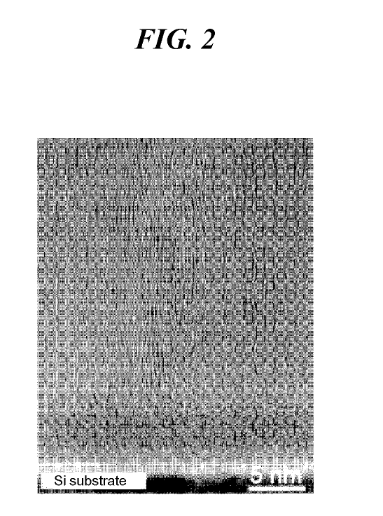

As can been seen from FIG. 2, the (0001) crystal face of the hBN layer is well arranged perpendicular to the substrate, and the distance between the (0001) faces is 3.328A, which is much longer than the length of the boron-nitrogen bond. Accordingly, when inert gas ions (For example, Ar ions having the ionic size of 3.76A) collide perpendicularly with the surface of hBN layer, they can be easily incorporated into the gap between the (0001) faces of hBN.

However, since the size of Ar ion is a little bigger than the gap between the (0001) faces, the Ar ion incorporated into the hBN layer induces the generation of compressive residual stress. Accordingly, higher concentration of Ar ion is expected to increase compressive residual stress in the hBN thin film.

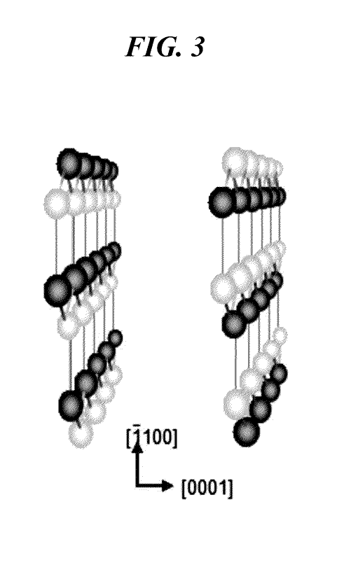

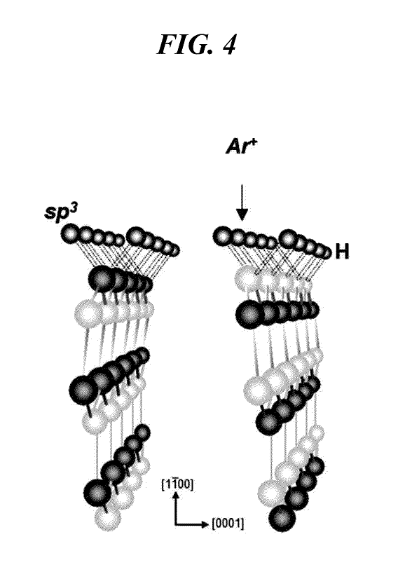

Further, the crystalline structure of hBN consists of hexagonal plates, which is similar to that of graphite. Accordingly, the crystalline structure of the growing (0001) face has a sp² structure as shown in FIG. 3. However, when a different atom is chemically adsorbed on to the surface of the hBN film, the surface structure of the film is changed. Particularly, it has been known that surface structure of hBN is changed from sp² to sp³, when hydrogen atom bonds to boron or nitrogen atom of the surface (I. Konya Shin et al. Dia. and Rel. Mat., 8, 2053 (1999)). As shown in FIG. 4, the distance between the (0001) faces is greatly reduced due to the bonds between hydrogen atom and boron or nitrogen atom.

The change of surface structure may influence on the deposition of hBN thin film as follows.

First, the volume of inert gas incorporated into the film can be reduced. Since the surface structure of hBN layer has the sp³ structure of FIG. 4, the space between the (0001) faces becomes narrow, and thus, the incorporation of inert gas ion is reduced, leading to a thin film having reduced residual stress.

Second, the critical ion energy required for the synthesis of cBN can be reduced. For the transition of sp² structure in the surface of hBN layer to sp³ structure, certain level of collision energy of the inert gas ions is required. However, the critical ion collision energy can be reduced since the surface structure has been transited from sp² to sp³ structure due to the hydrogen addition, and thus, residual stress of the thin film can be reduced.

The present invention provides a method which can reduce the content of inert gas incorporated into an hBN layer and the critical collision energy required for the synthesis of cBN.

According to the present invention, there is provided a method for depositing a cBN thin film on a substrate by carrying out physical vapor deposition under an inert gas atmosphere, wherein hydrogen is added to the inert gas in order to reduce the compressive residual stress of the deposited thin film.

According to the present invention, compressive residual stress in the deposited thin film may be considerably decreased compared with a conventional method, preferably 3 GPa or less.

According to the preferable example of the present invention, the volume of added hydrogen in an inert gas may be 1% to 20% based on the total volume of the inert gas and hydrogen, preferably 5% to 10%.

The inert gas used in the present invention may be N₂, Ar, He, Ne, or a mixture thereof, preferably a mixture of N₂ and Ar.

According to the preferable example of the present invention, the volume content of Ar of the inert gas is 80% to 95%.

The present invention may be applied any kind of substrates such as Si, tool steel, structural ceramics, etc.

Further, the deposition method used in the present invention includes sputtering, ion beam deposition, etc., preferably sputtering. In case of sputtering, hBN, B₄C, preferably hBN may be used for a sputtering target.

Among the various sputtering methods, unbalanced magnetron sputtering (DBMS) is more preferable.

According to the preferable example of the present invention, UBMS may be carried out by using an hBN sputtering target having a diameter of 5 cm to 10 cm. The UBMS may be conducted by: connecting an RF power supply of 300 W to 500 W to a sputtering target; connecting a high frequency power supply of 100 kHz to 13.56 MHz to the substrate to apply a bias of −60 V to −300 V; and carrying out the deposition under a pressure of 4 mtorr or less.

According to the preferable example of the present invention, the substrate may be cleaned for 1 min to 10 min under a bias voltage of −700 V to −300 V before deposition.

According to the inventive deposition method, it is possible to reduce adverse effects such as reduced content of cBN and increased oxidation sensitiveness, and also to reduce the compressive residual stress significantly, which leads to a deposit thin film having an excellent adhesion strength. Accordingly, the abrasive material produced by the inventive method has a deposited cBN thin film which does not peel off and also has an excellent hardness.

### EXAMPLES

Hereinafter, the following Examples are intended to further illustrate the present invention without limiting its scope.

### Example

### Deposition of cBN Thin Film Using an Inert Gas Mixture Added with Hydrogen

A cBN thin film was deposited on a Si substrate by earring out unbalanced magnetron sputtering (UBMS). An hBN target (LTS chemical, USA) of 99.9% purity and having a diameter of 50 mm was used for a sputtering target.

The RF power supply of 400 W was connected to the hBN target, and a high frequency power supply of 200 kHz was connected to the substrate to apply a bias. A distance between the substrate and the target was fixed at 10 cm.

Before carrying out deposition, the Si substrate was laid on a support and depressurized to 1×10⁻⁵ mtorr, and Ar was introduced to perform dry cleaning for 10 min with application of a bias voltage of −400 V.

After the cleaning, nitrogen was added to maintain a gas composition of Ar—N₂(90/10, v/v), and an RF power supply of 400 W was applied to the target. A bias voltage of −70 V was applied to generate plasma after adding hydrogen to the gas mixture, and the deposition was initialized.

The content of added hydrogen varied among 2.5%, 5%, 10%, 15%, and 20% based on the total volume of the mixed gas to obtain a substrate having a deposited cBN thin film.

The substrate having the deposited film was subjected to SEM, TEM, RBS, and FT-IR analyses. Further, the degree of flexure after Si strip deposition was measured, and the residual stress was calculated.

### Comparative Example

### Deposition of cBN Thin Film Using an Inert Gas Mixture without Adding Hydrogen

A cBN thin film was deposited by the same procedure using Ar—N₂ gas mixture (90/10, v/v) without adding hydrogen.

### EXPERIMENTAL EXAMPLES

### Experimental Example 1

### FT-IR Analysis

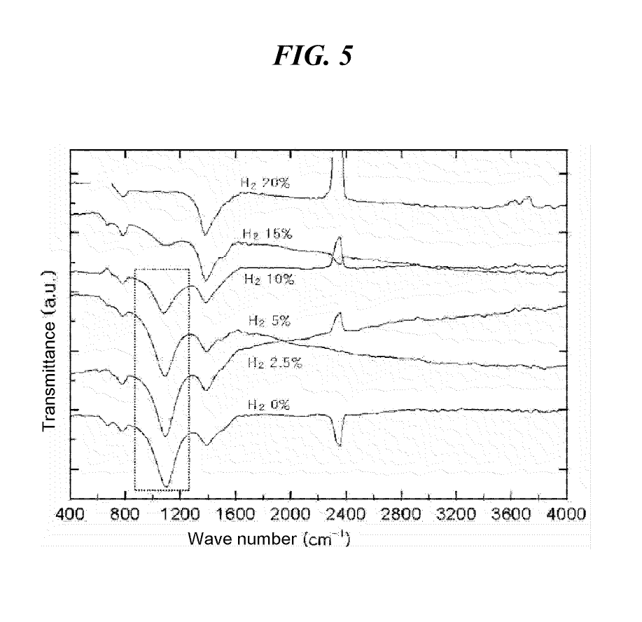

The thin films obtained in Example and Comparative Example were subjected FT-IR analysis, and the result are shown in FIG. 5. In FIG. 5, a peak attributed to cBN is observed near 1080 cm⁻¹, and two peaks attributed to hBN are observed at 780 cm⁻¹ and 1380 cm⁻¹. Up to 10% of hydrogen addition a considerable change of cBN content was not detected.

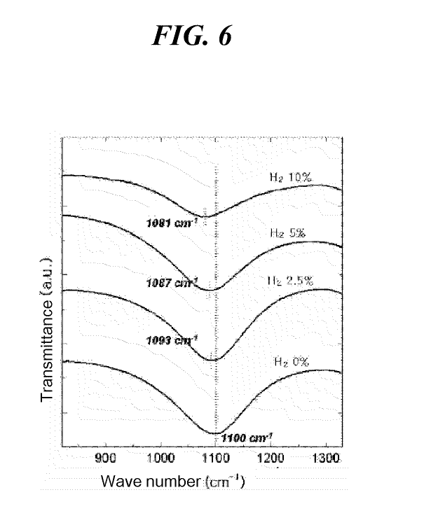

Meanwhile, compressive residual stress can be estimated from the change of peak position, because the cBN peak position depends on the bond length between atoms. FIG. 6 shows an enlarged cBN peak in FIG. 5. In FIG. 6, the peak position (wave number) decreases as the content of added hydrogen increases. The decrease in wave number means that the degree of lattice constant approaches the cBN lattice constant without stress, and thus the residual stress of the film has been reduced according to the addition of hydrogen.

### Experimental Example 2

### Residual Stress Analysis

An Si strip having a thick near of 100 μm and a size of 2 mm×40 mm was deposited on the thin films obtained in Example and Comparative Example, and then the degree of flexure was measured to calculate compressive residual stress.

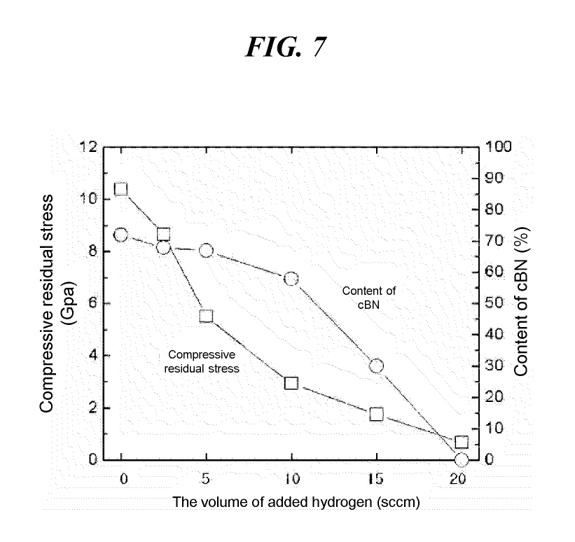

FIG. 7 shows the change of cBN content in the thin films and the change of compressive residual stress of the thin films.

In FIG. 7, up to 10% of hydrogen addition, although the content of cBN has not been changed a lot compressive residual stress has been decreased about 70%. This shows that compressive residual stress can be considerably reduced by the addition of hydrogen.

### Experimental Example 3

### Ar Content Analysis

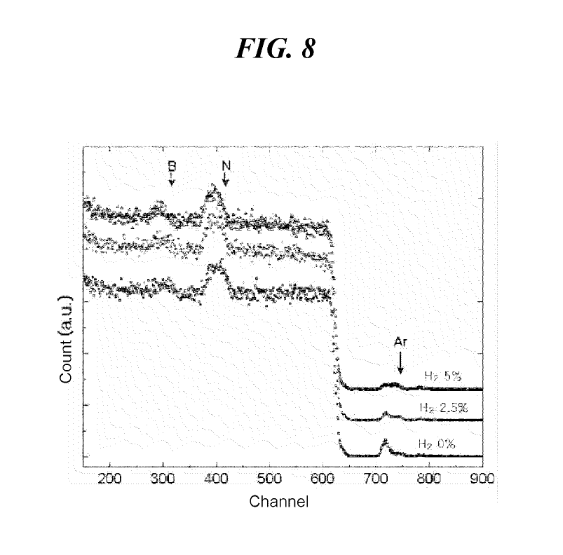

FIG. 8 shows the change of Ar content incorporated into the thin film as a function of the volume of added hydrogen, measured by using RBS (Rutherford back scattering) method.

In FIG. 8, the content of Ar in the thin film was decreased markedly according to the volume of added hydrogen. This shows that the decrease of the residual stress in the thin film is related with the content of Ar incorporated into the film, which is caused by the change of the surface structure of hBN according to the addition of hydrogen.

### Experimental Example 4

### SEM Analysis

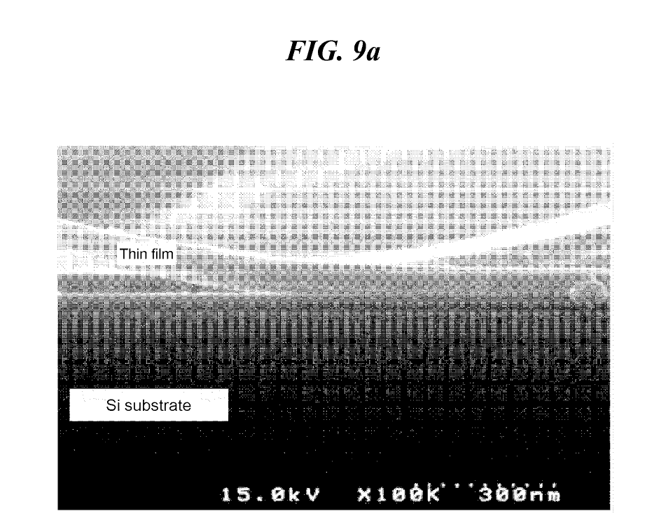

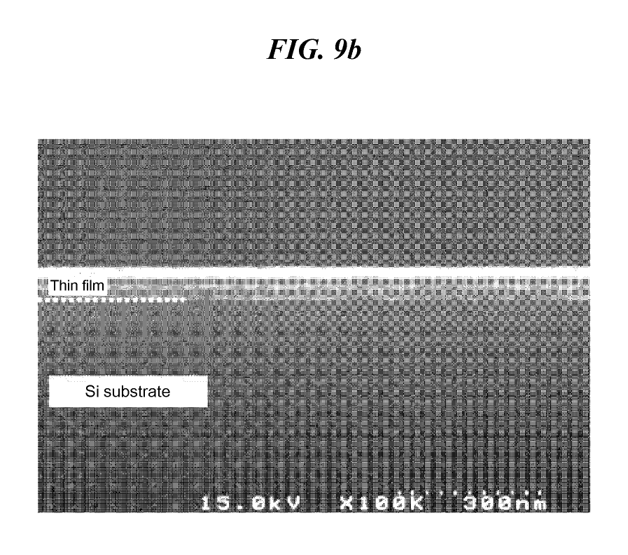

FIGS. 9a and 9b show SEM images of the deposited thin films of Comparative Example and Example, respectively. As can be seen from FIGS. 9a and 9b, while the thin film obtained in Comparative Example without adding hydrogen was peeled off from the Si substrate (FIG. 9a), the thin film obtained in Example through hydrogen addition was not peeled off from the Si substrate (FIG. 9b).

According to the inventive deposition method, it is possible to reduce adverse effects such as reduced content of cBN and increased oxidation sensitiveness, and also to reduce the compressive residual stress significantly, which leads to a deposit thin film having an excellent adhesion strength. Accordingly, the abrasive material produced by the inventive method has a deposited cBN thin film which does not peel off and also has an excellent hardness.

While the invention has been described with respect to the specific embodiments, it should be recognized that various modifications and changes may be made by those skilled in the art to the invention which also fall within the scope of the invention as defined as the appended claims.

What is claimed is:

1. A method for depositing a cBN thin film on a substrate by carrying out physical vapor deposition under an inert gas atmosphere, wherein hydrogen is added to the inert gas in order to reduce the compressive residual stress of the deposited thin film.

2. The method according to claim 1, wherein the compressive residual stress of the deposited thin film is 3 GPa or less.

3. The method according to claim 1, wherein the volume content of hydrogen is 1% to 20% based on the total volume of the inert gas and hydrogen mixture.

4. The method according to claim 1, wherein the volume content of hydrogen is 5% to 10% based on the total volume of the inert gas and hydrogen mixture.

5. The method according to claim 1, wherein the inert gas is selected from N₂, Ar, He, Ne and a mixture thereof.

6. The method according to claim 1, wherein the inert gas is a mixture of N₂ and Ar.

7. The method according to claim 6, wherein the volume content of Ar of the inert gas is 80% to 95%.

8. The method according to claim 1, wherein the deposition is carried out by sputtering.

9. The method according to claim 8, wherein the sputtering is conducted by unbalanced magnetron sputtering.

10. The method according to claim 9, wherein the unbalanced magnetron sputtering is conducted by: connecting an RF power supply of 300 W to 500 W to a sputtering target; connecting a high frequency power supply of 100 kHz to 13.56 MHz to the substrate to apply a bias of −60 V to −300 V; and carrying out the deposition under a pressure of 4 mtorr or less.
